(19) United States
(12) Patent Application Publication
(10) Pub. No.: US 2026/0333907 A1
(43) Pub. Date: Oct. 22, 2026

(54) SOLID-STATE IMAGING DEVICE

(71) Applicant: SONY SEMICONDUCTOR SOLUTIONS CORPORATION, KANAGAWA (JP)

(72) Inventors: Yuki SHIRAI, KANAGAWA (JP); Ryosuke NAKAMURA, KANAGAWA (JP); Ryosuke YAMACHI, KANAGAWA (JP); Naoki SAKA, KANAGAWA (JP)

(21) Appl. No.: 19/117,425

(22) PCT Filed: Sep. 21, 2023
(86) PCT No.: PCT/JP2023/034200

§ 371 Date: Apr. 1, 2025

(30) Foreign Application Priority Data
Oct. 6, 2022 (JP) 2022-161827

(51) Int. Cl. H10F 39/00

(52) U.S. Cl. CPC H10F 39/80377

(57) ABSTRACT

The present disclosure relates to a solid-state imaging device designed to improve the characteristics of pixels. There is provided a solid-state imaging device including a pixel array section having pixels arranged two-dimensionally therein, each of the pixels including a photoelectric conversion element and a pixel transistor. The pixel transistor includes a transistor having a structure in which impurities are injected into a nonlinear-shaped channel in planar view with use of a self-aligned mask corresponding to a gate electrode. The present disclosure can be applied to CMOS solid-state imaging devices, for example.

### TECHNICAL FIELD

The present disclosure relates to a solid-state imaging device. More particularly, the disclosure relates to a solid-state imaging device designed to improve the characteristics of pixels.

### BACKGROUND ART

In recent years, there have been proposed back-illuminated solid-state imaging devices that emit light from the side of the substrate opposite to the side thereof where the wiring layer is formed (e.g., see PTL 1). As the downscaling of the pixel structure advances, some back-illuminated solid-state imaging devices may be furnished with pixel transistors having L-shaped channels due to layout constraints.

### CITATION LIST

### Patent Literature

### PTL 1

PCT Patent Publication No. WO2017/169754

### SUMMARY

### Technical Problem

In such a solid-state imaging device described above, desired characteristics of the pixels may not be obtained under layout constraints. It has thus been advised to improve the pixel characteristics.

The present disclosure has been made in view of the above circumstances and proposes improving the pixel characteristics.

### Solution to Problem

According to one aspect of the present disclosure, there is provided a solid-state imaging device including a pixel array section having a plurality of pixels arranged two-dimensionally therein, each of the pixels including a photoelectric conversion element and a pixel transistor, in which the pixel transistor includes a transistor having a structure in which impurities are injected into a nonlinear-shaped channel in planar view with use of a self-aligned mask corresponding to a gate electrode.

In the solid-state imaging device according to the aspect of the present disclosure, there is provided the pixel transistor of the pixels arranged two-dimensionally in the pixel array section, the pixel transistor having the structure in which the impurities are injected into the nonlinear-shaped channel in planar view with use of the self-aligned mask corresponding to the gate electrode.

According to another aspect of the present disclosure, there is provided a solid-state imaging device including a pixel array section having a plurality of pixels arranged two-dimensionally therein, each of the pixels including a photoelectric conversion element and a pixel transistor, in which the pixel transistor includes a transistor having a structure in which an amount of overlap of a first impurity region on a source side with a gate electrode and a side wall is different from an amount of overlap of a second impurity region on a drain side with the gate electrode and the side wall.

In the solid-state imaging device according to the other aspect of the present disclosure, there is provided the pixel transistor of the pixels arranged two-dimensionally in the pixel array section, the pixel transistor having the structure in which the amount of overlap of the first impurity region on the source side with the gate electrode and the side wall is different from the amount of overlap of the second impurity region on the drain side with the gate electrode and the side wall.

Incidentally, the solid-state imaging device according to one aspect of the present disclosure may be either an independent device or an internal block constituting part of a single device.

### Brief Description of Drawings

FIG. 1 is a diagram depicting an exemplary configuration of an embodiment of a solid-state imaging device to which the present disclosure is applied.

FIG. 2 is a plan view depicting an exemplary configuration of a pixel.

FIG. 3 is a cross-sectional diagram taken on line A-A′ of the pixel in FIG. 2.

FIG. 4 is a timing chart indicating how pixel transistors are driven.

FIG. 5 gives diagrams indicating a manufacturing method including processes for forming a structure of the present disclosure.

FIG. 6 gives other diagrams indicating the manufacturing method including other processes for forming the structure of the present disclosure.

FIG. 7 gives diagrams explaining the effect exerted by a structure in which impurities are injected into a nonlinear-shaped channel with use of a self-aligned mask.

FIG. 8 gives other diagrams explaining the effect exerted by the structure in which impurities are injected into the nonlinear-shaped channel with use of the self-aligned mask.

FIG. 9 is a plan view depicting an exemplary configuration of a pixel.

FIG. 10 gives a plan view and a cross-sectional diagram taken on line A-A′ of the pixel in FIG. 9.

FIG. 11 gives a plan view and a cross-sectional diagram taken on line A-A′ of the pixel in FIG. 9.

FIG. 12 is a cross-sectional diagram depicting an exemplary configuration of a pixel.

FIG. 13 is a cross-sectional diagram depicting another exemplary configuration of a pixel.

FIG. 14 gives a plan view and a cross-sectional diagram depicting an exemplary configuration of a pixel.

FIG. 15 gives a plan view and a cross-sectional diagram depicting another exemplary configuration of a pixel.

FIG. 16 is a plan view depicting an exemplary configuration of a pixel transistor.

FIG. 17 is a plan view depicting another exemplary configuration of a pixel transistor.

FIG. 18 is a cross-sectional diagram depicting another exemplary configuration of a pixel transistor.

FIG. 19 is a diagram indicating a manufacturing method including a process for forming a structure of the present disclosure.

FIG. 20 is a graphic representation explaining the effect of electric field relaxation brought about by the structure of the present disclosure.

FIG. 21 is a plan view depicting an exemplary configuration of a pixel transistor.

FIG. 22 is a plan view depicting another exemplary configuration of a pixel transistor.

FIG. 23 is a cross-sectional diagram depicting another exemplary configuration of a pixel transistor.

FIG. 24 is a block diagram depicting an exemplary configuration of electronic equipment carrying the solid-state imaging device to which the present disclosure is applied.

FIG. 25 is a block diagram depicting an example of schematic configuration of a vehicle control system.

FIG. 26 is a diagram of assistance in explaining an example of installation positions of an outside-vehicle information detecting section and an imaging section.

### DESCRIPTION OF EMBODIMENTS

### First Embodiment

### Configurations of the Device

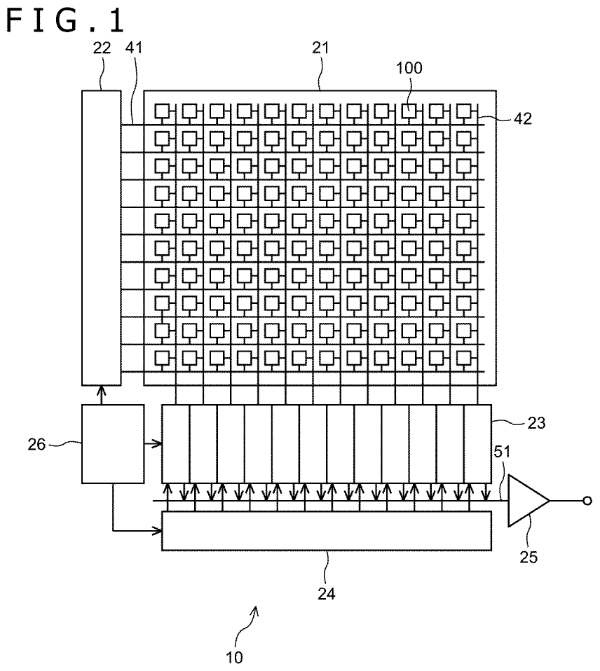

FIG. 1 is a diagram depicting an exemplary configuration of an embodiment of a solid-state imaging device to which the present disclosure is applied.

In FIG. 1, a solid-state imaging device 10 is of the CMOS (Complementary Metal Oxide Semiconductor) type. The solid-state imaging device 10 also may be a back-illuminated solid-state imaging device. The solid-state imaging device 10 includes a pixel array section 21, a vertical drive section 22, column signal processing sections 23, a horizontal drive section 24, an output section 25, and a control section 26.

The pixel array section 21 has multiple pixels 100 arranged two-dimensionally on a semiconductor substrate typically constituted by silicon (Si). With the multiple pixels 100 arranged in a two-dimensional matrix pattern, the pixel array section 21 has a pixel drive line 41 formed for each row of the pixels and connected to the vertical drive section 22. The pixel array section 21 further has a vertical signal line 42 formed for each column of the pixels and connected to the column signal processing sections 23.

The vertical drive section 22, typically including a shift register, an address decoder, or the like, drives the pixels 100 arranged in the pixel array section 21. Signals output from the pixels 100 and scanned selectively by the vertical drive section 22 are supplied to the column signal processing sections 23 via the vertical signal lines 42.

For each pixel column of the pixel array section 21, the column signal processing sections 23 perform predetermined signal processing (e.g., noise removal, sampling, and the like) on the respective signals output via the vertical signal lines 42 from the pixels 100 of the selected rows. The column signal processing sections 23 temporarily hold the signals thus processed.

The horizontal drive section 24, typically including a shift register, an address decoder, or the like, sequentially selects unit circuits corresponding to the pixel columns of the column signal processing sections 23. The signals processed by the column signal processing sections 23 following selective scanning by the horizontal drive section 24 are output to the output section 25 via a horizontal signal line 51.

The output section 25 performs predetermined signal processing on the signals sequentially input from each of the column signal processing sections 23 via the horizontal signal line 51. The output section 25 then outputs the resulting signals.

The control section 26 typically includes a timing generator that generates various timing signals, and the like. On the basis of the various timing signals thus generated by the timing generator, the control section 26 drive-controls the vertical drive section 22, the column signal processing sections 23, the horizontal drive section 24, and the like.

### First Configuration

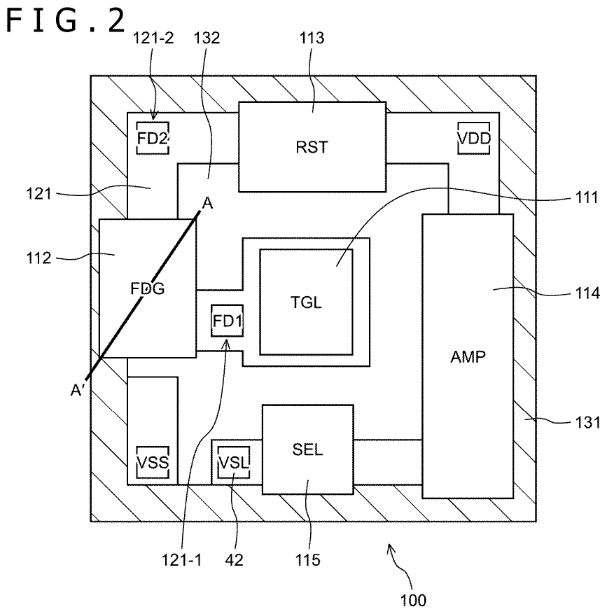

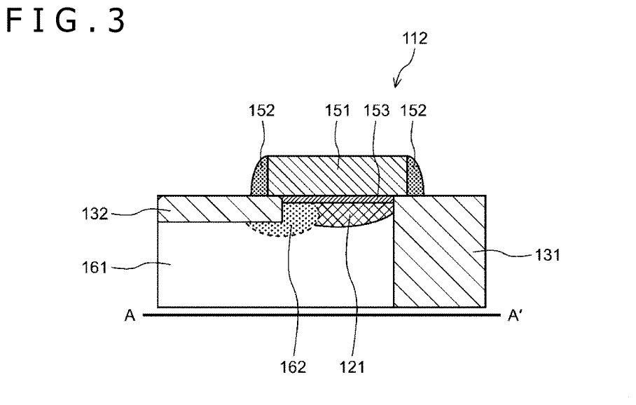

FIG. 2 is a plan view depicting an exemplary configuration of a pixel 100. FIG. 3 is a cross-sectional diagram taken on line A-A′ of the pixel 100 in FIG. 2. In the case where a stacking direction (depth direction) in which the constituent elements of the pixel are stacked one on top of another in the cross-sectional structure of FIG. 3 is regarded as a Z-direction in an XYZ-axis space, a plan view seen on an X-Y plane is indicated in FIG. 2. This relation between the plan view and the cross-sectional diagram also holds for the other views and diagrams to be discussed below.

The pixel 100 includes a photodiode as a photoelectric conversion element and pixel transistors. The pixel 100 is a square-unit pixel. The photodiodes of the pixels are isolated by element isolation sections 131 arranged in a square grid. Also, the elements in the pixel 100 are isolated by an element isolation section 132.

As depicted in FIG. 2, the pixel 100 has a transfer transistor 111, a capacitance switching transistor 112, a reset transistor 113, an amplification transistor 114, and a selection transistor 115 as the pixel transistors.

The transfer transistor 111 is interposed between the photodiode and an FD 121. In response to a drive signal TGL applied to its gate electrode, the transfer transistor 111 transfers an electrical charge stored in the photodiode to the FD 121. The FD 121 stands for a floating diffusion (FD) that converts the electrical charge from the photodiode into a voltage signal.

The FD 121 is connected with the capacitance switching transistor 112 and the reset transistor 113. In response to a drive signal FDG applied to its gate electrode, the capacitance switching transistor 112 switches FD capacitance of the FD 121. The FD 121 includes an FD 121-1 and an FD 121-2 with the capacitance switching transistor 112 interposed therebetween.

The reset transistor 113 is connected with the amplification transistor 114. In response to a drive signal RST applied to its gate electrode, the reset transistor 113 resets the input of the gate electrode of the amplification transistor 114 to a predetermined potential. The amplification transistor 114 has its gate electrode connected to the FD 121 and its drain connected to a power supply voltage (VDD). The amplification transistor 114 amplifies the electrical charge obtained by photoelectric conversion by the photodiode.

The selection transistor 115 is connected interposingly between the source of the amplification transistor 114 and the vertical signal line 42. In response to a drive signal SEL applied to its gate electrode, the selection transistor 115 controls conduction between the source of the amplification transistor 114 and the vertical signal line 42. When conduction is caused between the source of the amplification transistor 114 and the vertical signal line 42, allowing the pixel 100 to be selected, the signal from the amplification transistor 114 is read out to the column signal processing section 23 via the vertical signal line 42.

Here, the capacitance switching transistor 112 has an L-shaped nonlinear channel 121. That is, the capacitance switching transistor 112 is shaped in such a manner that the channel 121 has a right-angle region in planar view. In the capacitance switching transistor 112, as depicted in FIG. 3, the region of the channel 121 is formed by injecting n-type impurities (impurity ions) into a silicon substrate 161 having p-type regions. An impurity region 162 is also formed by injecting p-type impurities (impurity ions) into the nonlinear-shaped channel 121 with use of a self-aligned mask. The self-aligned mask is formed corresponding to a gate electrode 151 of the capacitance switching transistor 112. A side wall 152 is formed laterally on the gate electrode 151.

The element isolation section 131 has an element isolation structure in which trenches penetrate through the silicon substrate 161 (i.e., through-trenches) in the stacking direction. The through-trenches are embedded with side wall films and fillers. The element isolation section 132 has an engraved element isolation structure in which the silicon substrate 161 is engraved in the stacking direction and embedded with an oxide.

In this manner, the pixel 100 has the photodiode and the pixel transistors including the capacitance switching transistor 112 having the structure in which impurities are injected into the nonlinear-shaped channel 121 with use of the self-aligned mask. The pixel 100 also has the element isolation structure constituted by the element isolation sections 131 and 132. It is to be noted that, in the case where not only the capacitance switching transistor 112, but also transistors having nonlinear-shaped channels are arranged, the relevant transistor can also be given a structure in which impurities are injected into the nonlinear-shaped channels with use of the self-aligned mask. In the plan view of FIG. 2, for example, the amplification transistor 114 having a nonlinear-shaped channel may have a structure in which impurities are injected with use of the self-aligned mask.

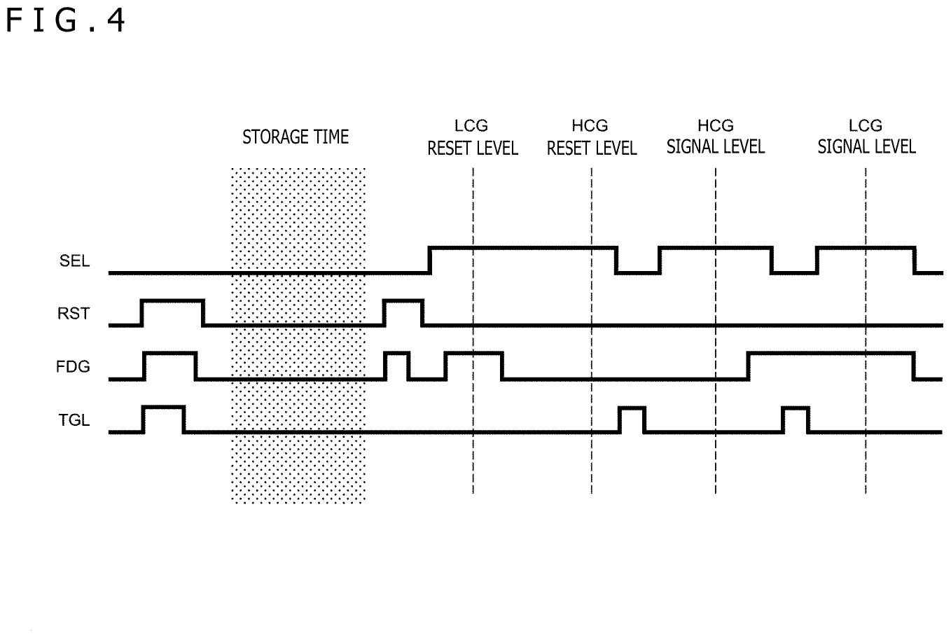

FIG. 4 is a timing chart indicating how the pixel transistors of the pixel 100 are driven. FIG. 4 indicates a typical readout operation of the pixel 100. Signs SEL, RST, FDG, and TGL stand for drive signals to be applied to the gate electrode of each of the transistors in the plan view of FIG. 2. As depicted in FIG. 4, the transistors operate in response to the respective drive signals to provide sequentially an LCG (Low Conversion Gain) reset level, an HCG (High Conversion Gain) reset level, an HCG signal level, and an LCG signal level. These signal levels and reset levels are used to perform sampling processes such as CDS (Correlated Double Sampling). This makes it possible to read out the signal obtained from the electrical charge stored in the photodiode.

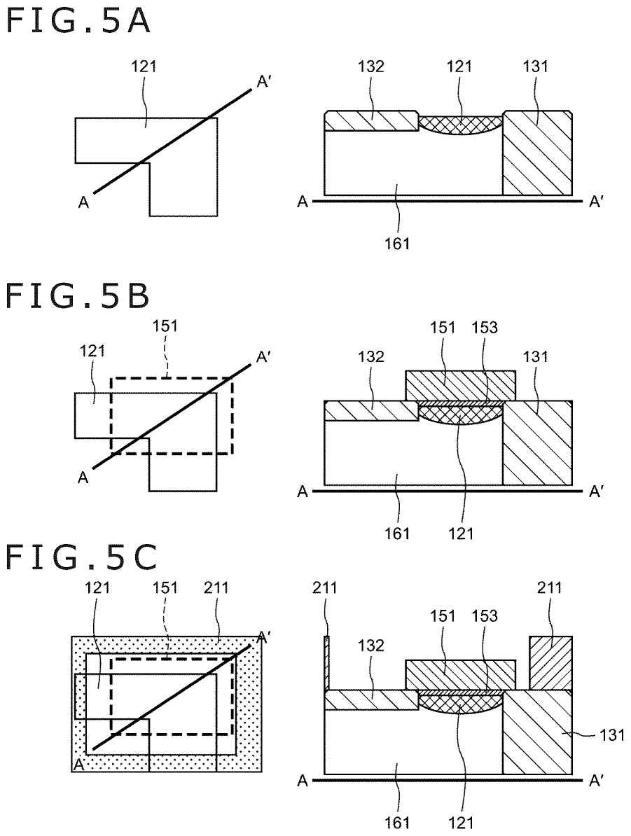

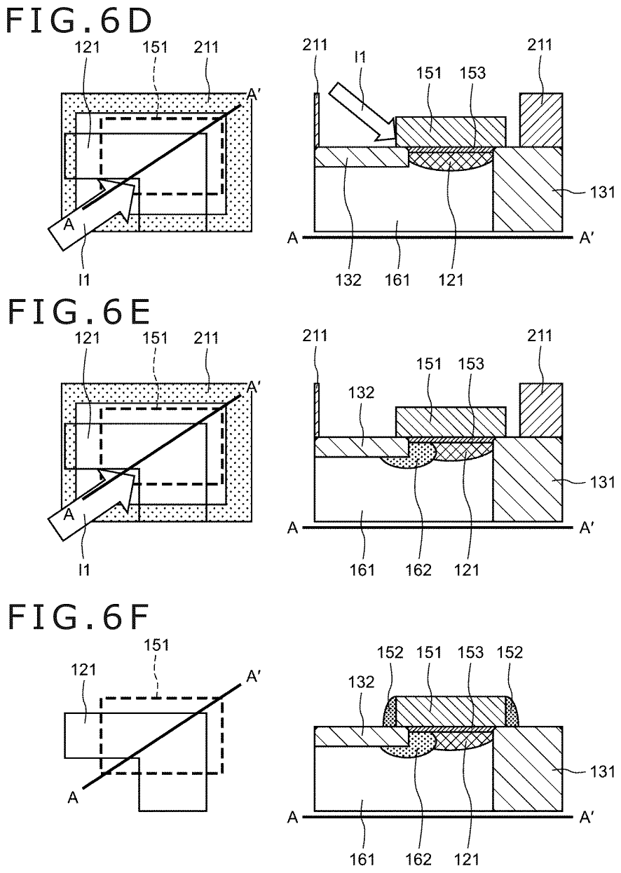

FIGS. 5 and 6 are diagrams indicating the manufacturing method including processes for forming a structure (i.e., cross-sectional structure in FIG. 3). Subfigures A through F in FIGS. 5 and 6 give plan views and cross-sectional diagrams corresponding to the processes involved. The cross-sectional diagrams are each taken on line A-A′ in the plan views.

The process in Subfigure A of FIG. 5 involves forming through-trenches in the silicon substrate 161, having the trenches embedded with side wall films, fillers, and the like to form the element isolation section 131, and engraving regions to be embedded with oxides to form the element isolation section 132. The process in Subfigure A of FIG. 5 further involves injecting n-type impurities into the silicon substrate 161 to form the region of the channel 121. The process in Subfigure B of FIG. 5 involves forming an oxide film 153 over the channel 121 and further forming the gate electrode 151 typically made of polysilicon (poli-Si), a metal, and the like over an upper surface of the oxide film 153.

The process in Subfigure C of FIG. 5 involves forming a resist pattern 211 having a wide opening inside of the nonlinear-shaped channel 121. That is, the resist pattern 211 is formed in a manner having p-type impurities injected into the inside of the L-shaped channel 121. The processes in Subfigures D and E in FIG. 6 involve using the resist pattern 211 to inject p-type impurities obliquely at a tilt angle into the inside of the L-shaped nonlinear channel 121 (as indicated by arrow I1 in the drawings). The tilt angle is a predetermined angle relative to a normal line to the principal surface of the substrate. For example, the tilt angle is formed between a normal line to the surface of the silicon substrate 161 and an ion beam.

When p-type impurities are injected, a self-aligned mask formed corresponding to the gate electrode 151 is used to form a p-type impurity region 162 as depicted in Subfigure E of FIG. 6. In this manner, with the previously formed gate electrode 151 used as the self-aligned mask, i.e., with the gate electrode 151 handled as a pseudo-mask, part of the p-type impurities injected obliquely at a tilt angle is impeded from entering the silicon substrate 161 (i.e., not injected thereinto). As a result of this, when the gate electrode 151 varies due to manufacturing process deviation, the gate electrode 151 serves as a basis for adaptively correcting the amount of p-type impurities being injected.

The process in Subfigure F of FIG. 6 involves removing the resist pattern 211 to form the side wall 152 on the gate electrode 151. The above processes form the cross-sectional structure depicted in FIG. 3.

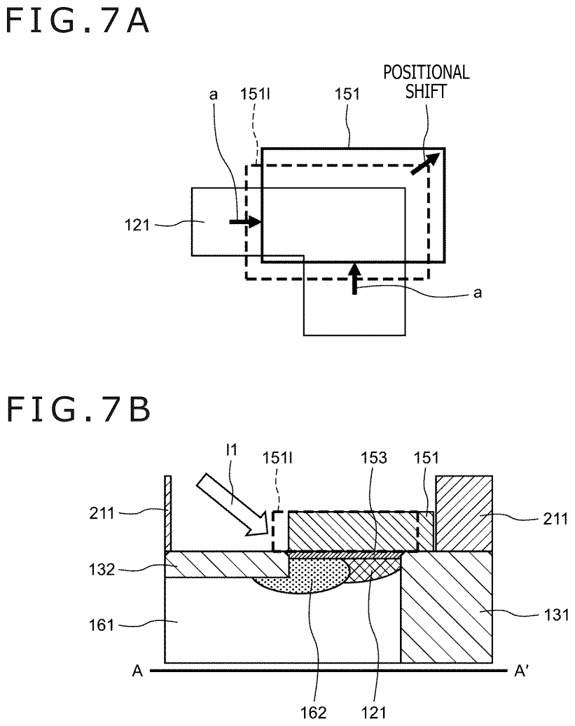

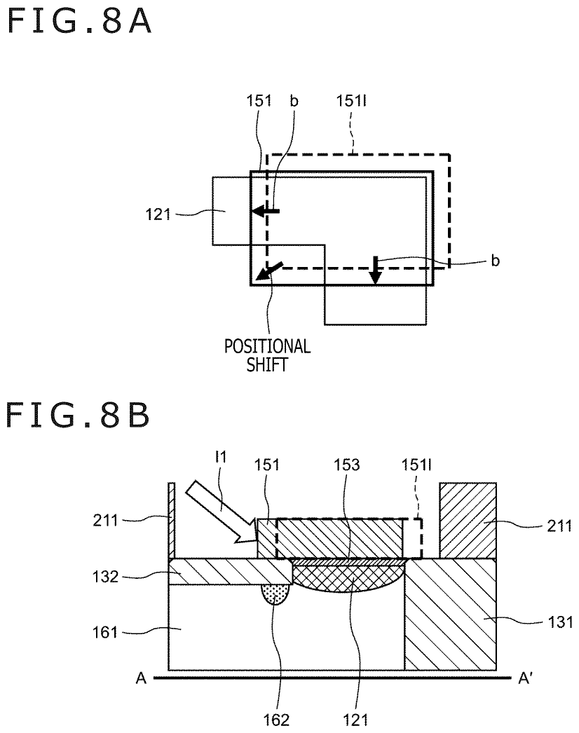

Here, explained below with reference to FIGS. 7 and 8 is the effect exerted by the structure of the present disclosure, i.e., a structure in which p-type impurities are injected into the nonlinear-shaped channel with use of the self-aligned mask. When the pixel transistors are arranged, there are cases where the nonlinear channel structure such as the L-shape is adopted due to layout constraints. In the structure of the transistor having the nonlinear-shaped channel, a gate electrode position shift caused by manufacturing process deviations varies the channel length. This affects electrical characteristics such as threshold voltage. In particular, a gate electrode position shift toward the outside or the inside of the right-angle-shaped channel affects the channel length in two directions. The gate electrode position shift thus leads to the problem of increasing individual differences.

FIG. 7 indicates a structure in which the gate electrode position shifts toward the outside. In FIG. 7, solid lines denote the actual position of the gate electrode 151, and broken lines 151I represent an ideal position of the gate electrode 151. As depicted in the plan view of Subfigure A in FIG. 7, if the actual position of the gate electrode 151 shifts outward from the ideal position, the channel length is shortened (as indicated by arrows “a” in two directions in the drawing), which lowers the transistor threshold voltage. In the case where the position of the gate electrode 151 shifts outward in the structure of the present disclosure, the amount (dose amount) of injected p-type impurities is increased by the self-aligned mask formed corresponding to the outward-shifting gate electrode 151, as depicted in the cross-sectional diagram of Subfigure B in FIG. 7. This makes it possible to suppress the decrease in the transistor threshold voltage.

FIG. 8 indicates the structure in which the gate electrode position shifts inward. As depicted in the plan view of Subfigure A in FIG. 8, where the actual position of the gate electrode 151 shifts inward relative to the ideal position indicated by broken lines 151I, the channel length is elongated (as indicated by arrows “b” in two directions in the drawing), which raises the transistor threshold voltage. In the case where the position of the gate electrode 151 shifts inward in the structure of the present disclosure, the amount (dose amount) of injected p-type impurities is decreased by the self-aligned mask formed corresponding to the inward-shifting gate electrode 151, as depicted in the cross-sectional diagram of Subfigure B in FIG. 8. This makes it possible to suppress the increase in the transistor threshold voltage.

In the structure of the present disclosure described above, the amount of injected p-type impurities is varied through self-alignment, which suppresses the individual differences of the electrical characteristics attributable to deviations in the gate electrode manufacturing process. In particular, in the case where the element isolation section 131 is formed with an element isolation structure that uses through-trenches, the inability to arrange the pixel transistors over the element isolation section 131 tends to produce a transistor structure in which channels having nonlinear shapes are laid out. This issue can easily be dealt with by adopting the structure of the present disclosure.

### Second Configuration

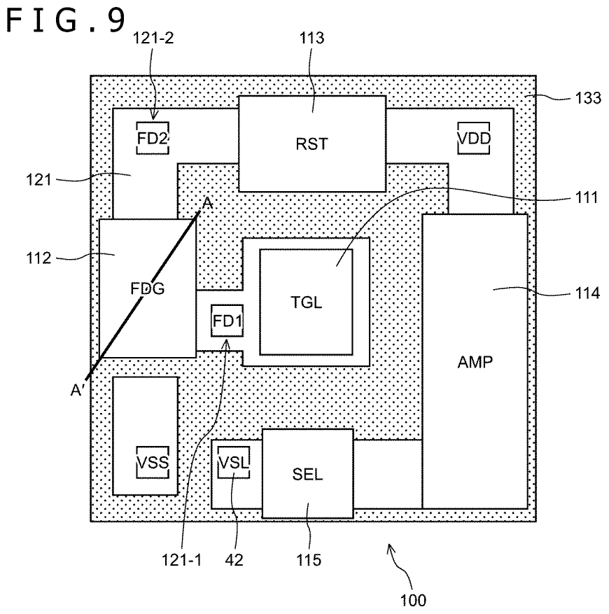

FIG. 9 is a plan view depicting an exemplary configuration of a pixel 100.

As with the pixel 100 in the plan view of FIG. 2, the pixel 100 in the plan view of FIG. 9 has a photodiode and pixel transistors. The pixel transistors include the transfer transistor 111, the capacitance switching transistor 112, the reset transistor 113, the amplification transistor 114, and the selection transistor 115.

Compared with the pixel 100 in the plan view of FIG. 2, the pixel 100 in the plan view of FIG. 9 has its photodiode isolated by injection of impurities 133 into the silicon substrate 161. That is, the pixel 100 in FIG. 9 has an element isolation structure based on impurity injection, without recourse to the element isolation structure with through-trenches. In FIG. 9 as well, the capacitance switching transistor 112 has an L-shaped nonlinear channel 121.

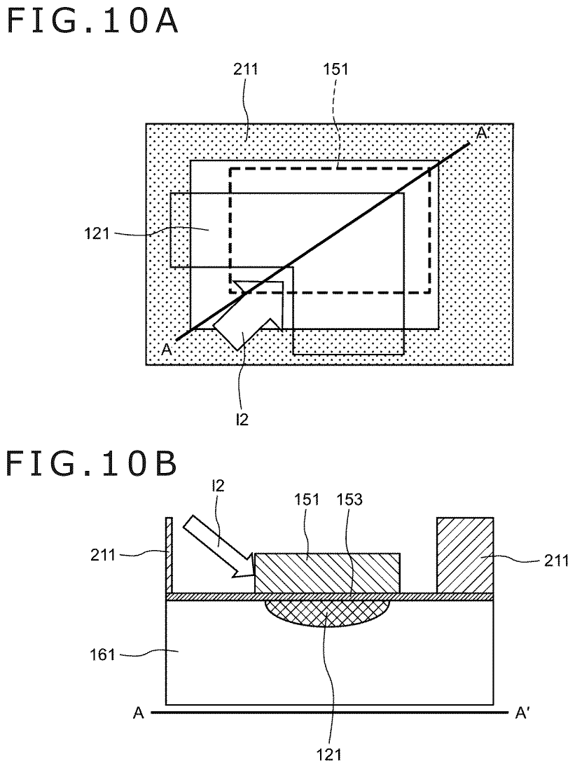

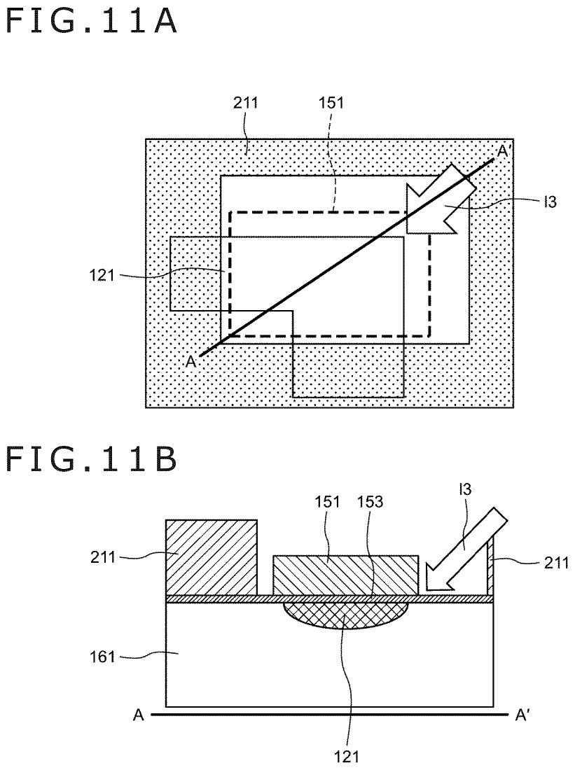

FIGS. 10 and 11 give cross-sectional diagrams taken on line A-A′ of the pixel 100 in FIG. 9. As illustrated in FIG. 10, the capacitance switching transistor 112 has a structure in which impurities are injected into the nonlinear-shaped channel 121 with use of a self-aligned mask. Specifically, as depicted in the plan view of Subfigure A in FIG. 10, there is formed a resist pattern 211 having a wide opening inside of the L-shaped channel 121, with p-type impurities injected obliquely at a tilt angle into the inside of the L-shaped channel 121 (as indicated by arrow I2 in the drawings). At this point, as illustrated in the cross-sectional diagram of Subfigure B in FIG. 10, the previously formed gate electrode 151 is used as the self-aligned mask impeding part of p-type impurities from getting injected into the silicon substrate 161. This makes it possible adaptively to correct the amount of injected p-type impurities when the gate electrode 151 positionally shifts due to manufacturing process deviations.

Instead of having p-type impurities injected into the inside of the nonlinear-shaped channel 121, n-type impurities may be injected into the outside of the nonlinear channel 121 as depicted in FIG. 11. Specifically, as illustrated in the plan view of Subfigure A in FIG. 11, there is formed a resist pattern 211 having a wide opening outside of the L-shaped channel 121, with n-type impurities injected obliquely at a tilt angle into the outside of the L-shaped channel 121 (as indicated by arrow I3 in the drawings). At this point, as illustrated in the cross-sectional diagram of Subfigure B in FIG. 11, the previously formed gate electrode 151 is used as the self-aligned mask impeding part of n-type impurities from getting injected into the silicon substrate 161. Thus, when n-type impurities are injected into the outside of the L-shaped channel 121, as in the case of p-type impurities injected into the inside of the L-shaped channel 121, it is possible to suppress threshold voltage deviations.

FIG. 10 depicts a structure in which p-type impurities are injected into the inside of the L-shaped channel 121, whereas FIG. 11 illustrates a structure where n-type impurities are injected into the outside of the L-shaped channel 121. These structures may each be used alone or may be combined in use. That is, according to the present disclosure, any one of three structures may be adopted: a structure in which p-type impurities are injected into the inside of the nonlinear-shaped channel 121, a structure where n-type impurities are injected into the outside of the nonlinear-shaped channel 121, or a structure in which p-type impurities are injected into the inside of the nonlinear channel 121 while n-type impurities are injected into the outside of the nonlinear channel 121.

Incidentally, in the second configuration as well, the capacitance switching transistor 112 is an exemplary pixel transistor to which the structure of the present disclosure is applied. In the case where a transistor having a nonlinear-shaped channel shape is arranged in the pixel 100, the relevant transistor may also be given a structure in which impurities are injected into the nonlinear-shaped channel with use of the self-aligned mask.

### Third Configuration

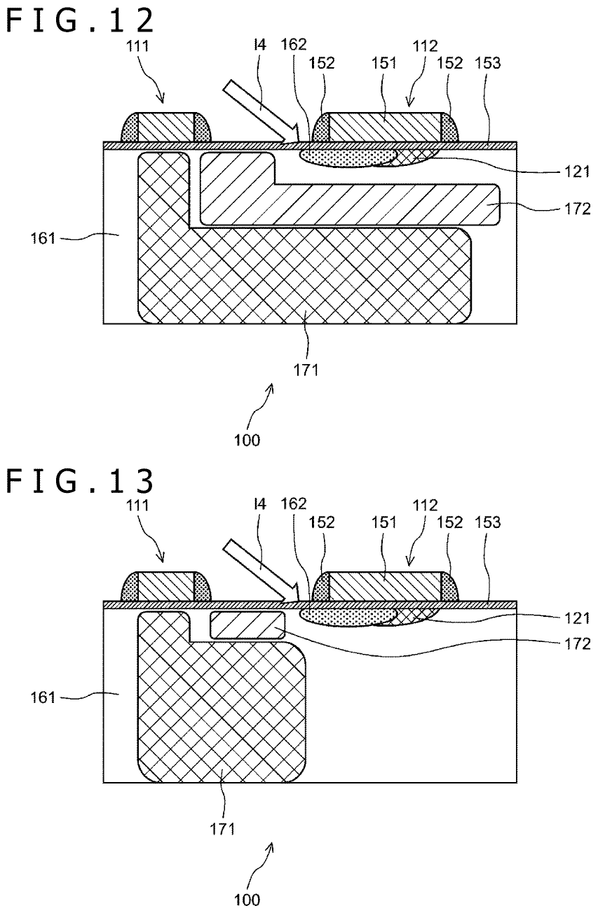

FIG. 12 is a cross-sectional diagram depicting an exemplary configuration of a pixel 100. FIG. 12 illustrates the relation between a photodiode and pixel transistors in the pixel 100.

In FIG. 12, a photodiode 171 formed in the silicon substrate 161 has an embedded structure and is located in a region away from the surface (Si interface) of the silicon substrate 161 in the stacking direction. An impurity region 172 injected with p-type impurities is formed between the photodiode 171 and the Si interface for isolation therebetween. That is, the pixel 100 in FIG. 12 has an embedded photodiode structure in which the photodiode 171 is positioned away from the Si interface and isolated therefrom by the p-type impurity region 172.

The transfer transistor 111 transfers the electrical charge stored in the photodiode 171 to the FD 121. The capacitance switching transistor 112 has the structure of the present disclosure, i.e., a structure in which impurities are injected (as indicated by arrow I4 in the drawing) into the nonlinear-shaped channel 121 with use of the self-aligned mask.

Here, depicted in FIG. 13 for comparison is the structure of a pixel 100 without recourse to the embedded photodiode structure. In FIG. 13, a photodiode 171 formed in the silicon substrate 161 is positioned near the Si interface. An impurity region 172 is formed over the photodiode 171. In the structure of the present disclosure, there is a larger area through which to inject p-type impurities into the nonlinear-shaped channel 121 with use of the self-aligned mask. For this reason, in the structure depicted in FIG. 13, i.e., in a structure where the embedded photodiode structure is not provided and the impurity region 172 is not arranged for photodiode isolation, there is a possibility of the photodiode 171 being affected by injection of impurities (as indicated by arrow I4 in the drawing) into the nonlinear-shaped channel 121 with use of the self-aligned mask. For example, injecting the impurities can vary the potential and reduce the photodiode 171 in size.

In view of the above, the embedded photodiode structure depicted in FIG. 12 is used for the pixel 100 as the structure of the pixel 100, with the p-type impurity region 172 arranged for further photodiode isolation. This makes it possible to prevent the photodiode 171 from being affected by injection of impurities into the nonlinear-shaped channel 121 with use of the self-aligned mask.

Incidentally, in the third configuration as well, the capacitance switching transistor 112 is an exemplary pixel transistor to which the structure of the present disclosure is applied. In the case where a transistor having a nonlinear-shaped channel is arranged in the pixel 100, that transistor may also use the structure of the present disclosure. In this case as well, the embedded photodiode structure depicted in FIG. 12 may be adopted with the p-type impurity region 172 arranged for isolation in the transistors (the other pixel transistors except for the capacitance switching transistor 112) to which the structure of the present disclosure is applied.

### Fourth Configuration

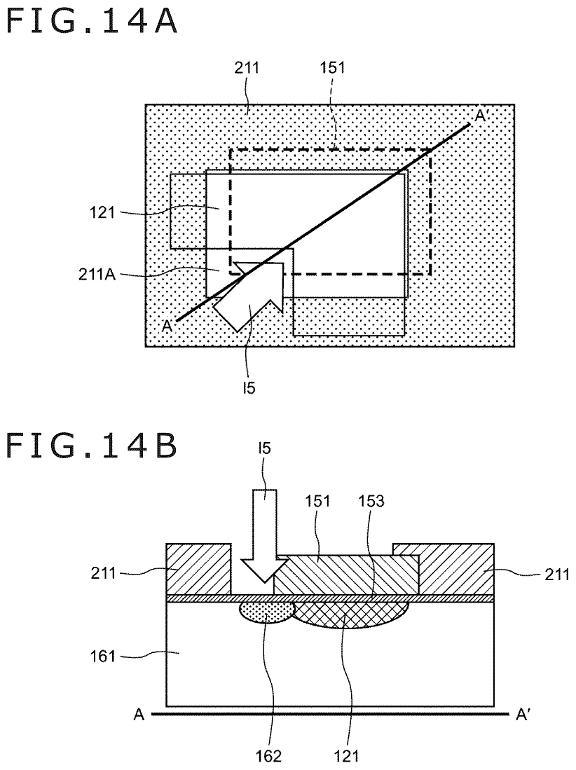

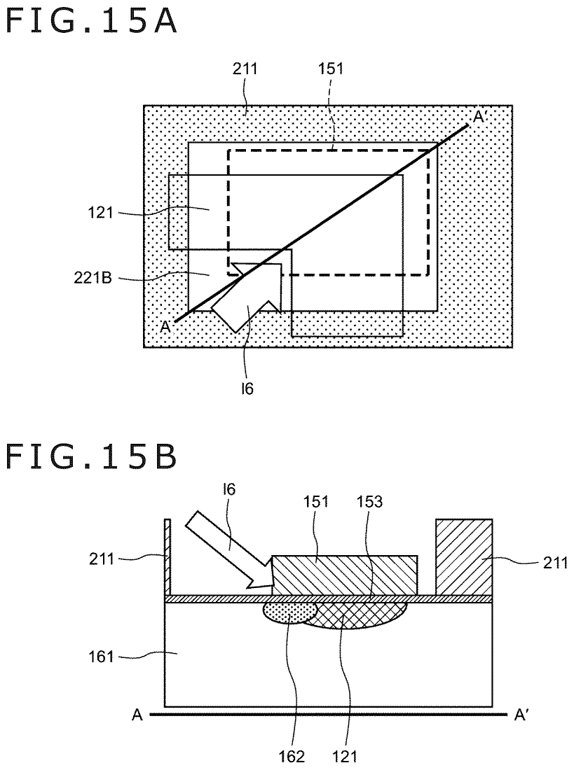

FIGS. 14 and 15 give plan views and cross-sectional diagrams depicting an exemplary configuration of the pixel 100. Here, FIG. 14 illustrates a structure in which impurities are injected vertically (in the stacking direction) into the nonlinear-shaped channel with use of the self-aligned mask, whereas FIG. 15 indicates a structure where impurities are injected obliquely at a tilt angle into the nonlinear-shaped channel with use of the self-aligned mask.

Specifically, as depicted in the plan view of Subfigure A in FIG. 14, a resist pattern 211 is formed and p-type impurities are injected into the inside of the L-shaped channel 121 (as indicated by arrow I5 in the drawing). At this point, as illustrated in the cross-sectional diagram of Subfigure B in FIG. 14, the previously formed gate electrode 151 is used as the self-aligned mask when the p-type impurities are vertically injected at no tilt angle into the inside of the L-shaped channel 121 (as indicated by arrow I5 in the drawing).

In contrast, as depicted in the plan view of Subfigure A in FIG. 15, a resist pattern 211 is formed, and p-type impurities are injected into the inside of the L-shaped channel 121 (as indicated by arrow I6 in the drawing). At this point, as illustrated in the cross-sectional diagram of Subfigure B in FIG. 15, the previously formed gate electrode 151 is used as the self-aligned mask when the p-type impurities are injected obliquely at a tilt angle into the inside of the L-shaped channel 121 (as indicated by arrow I6 in the drawing).

Here, in the case where impurities are injected at a tilt angle, as depicted in FIG. 15, the area of an opening 221B needs to be enlarged in consideration of shadowing by the resist pattern 211. In this case, p-type impurities injected over an extensive range can affect the photodiode and the other pixel transistors. In contrast, in the case where impurities are injected vertically, as depicted in FIG. 14, the area of an opening 211A of the resist pattern 211 can be reduced. This makes it possible to suppress the above-described adverse effect.

Specifically, in the case where the opening 211A in Subfigure A of FIG. 14 is compared with the opening 221B in Subfigure A of FIG. 15, the opening 211A is relatively smaller in area than the opening 221B, making it less likely for the injected impurities to affect the photodiode and the other pixel transistors. That is, according to the structure of the present disclosure, the injection of impurities at a tilt angle into the nonlinear channel 121 with use of the self-aligned mask is sufficiently effective. Still, in consideration of the above-described effect, the vertical injection of impurities is more preferable.

### Fifth Configuration

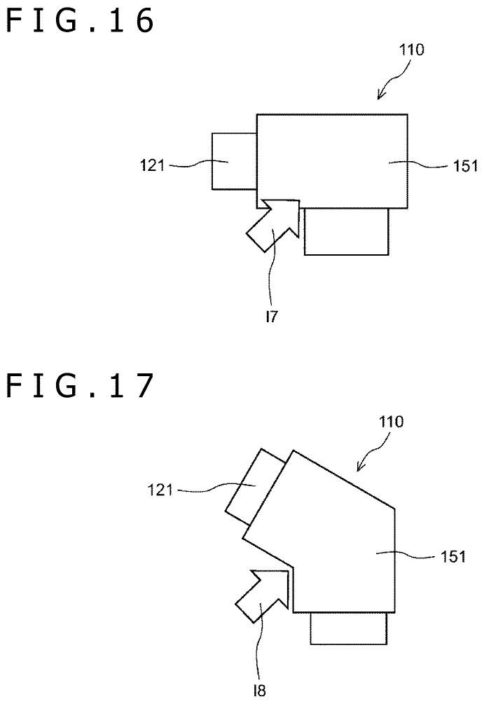

FIGS. 16 and 17 are plan views depicting an exemplary configuration of a pixel transistor. In FIGS. 16 and 17, a pixel transistor 110 may be the pixel transistor of the pixel 100 including the capacitance switching transistor 112 having the nonlinear-shaped channel 121, and other transistors. That is, the pixel transistor 110 is a pixel transistor to which the structure of the present disclosure is applied.

In FIG. 16, the pixel transistor 110 is shaped in such a manner that the channel 121 has a right-angle region (L-shape). Impurities are injected into the inside of the channel 121 (the inside of L-shape) with use of the self-aligned mask (as indicated by arrow I7 in the drawing). In the case where the channel 121 has the right-angle shape, a positional shift of the gate electrode 151 most affects the channel length. For this reason, as depicted in FIG. 16, a more advantageous effect is obtained in the case where impurities are injected into the channel 121 having the right-angle shape with use of the self-aligned mask. That is, the nonlinear-shaped channel 121 having the right-angle shape (L-shape) in particular is expected to be affected significantly by gate electrode manufacturing process deviations. Still, it is possible to suppress the individual differences of electrical characteristics in such a case.

In FIG. 17, the pixel transistor 110 is shaped in such a manner that a channel 121 has an obtuse-angle region. Impurities are injected into the inside (the inside of the shape) of the channel 121 with use of the self-aligned mask (as indicate by arrow I8 in the drawing). In the case where the channel 121 has an obtuse-angle shape, positional shifts of the gate electrode 151 affect the channel length less than in the case of the right-angle shape. Still, approximately similar effects are obtained by injection of impurities with use of the self-aligned mask. Further, it is possible to provide the pixel 100 with the pixel transistor 110 to which the structure of the present disclosure is applied and which has the channel 121 with the obtuse-angle shape instead of the right-angle shape. This makes it possible to increase the degree of freedom in arranging the pixel transistors in the pixel 100.

As described above, the structure of the present disclosure is one in which impurities are injected into the nonlinear-shaped channel of a given pixel transistor with use of the self-aligned mask corresponding to the gate electrode. Such a structure described above allows the amount of injected impurities to be varied through self-alignment even in the case of a gate electrode position shift upon the impurity injection. The structure thus suppresses the individual differences of electrical characteristics attributable to gate electrode manufacturing process deviations and the like. For example, as miniaturization of the pixel structure advances, there are cases where pixel transistors are given a nonlinear channel shape such as the L-shape due to layout constraints. However, with the transistor structure having the nonlinear channel shape, a gate electrode position shift caused by manufacturing process deviations varies the channel length. This in turn affects electrical characteristics such as threshold voltage. With the pixel transistor to which the structure of the present disclosure is applied, the amount of injected impurities is varied through self-alignment even in the case where the gate electrode position shifts, which suppresses the individual differences of electrical characteristics. This makes it possible to improve the characteristics of the pixel transistors. As a result, the characteristics of the pixels having such pixel transistors are improved.

### Second Embodiment

### First Configuration

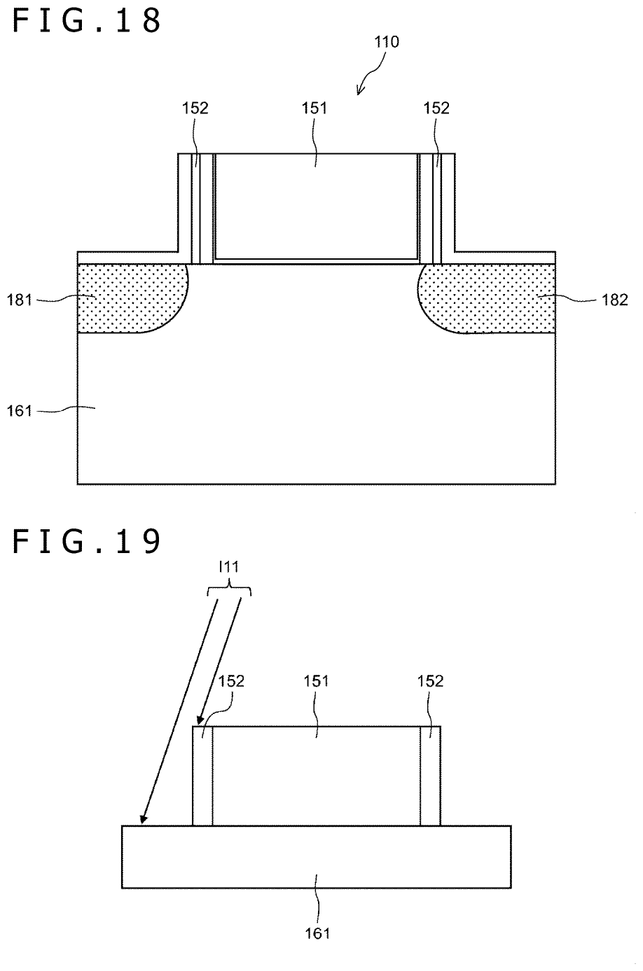

FIG. 18 is a cross-sectional diagram depicting an exemplary configuration of a pixel transistor in a pixel 100. The cross-sectional diagram of FIG. 18 indicates the stacking direction (depth direction) in which the constituent elements of the pixel 100 are stacked.

The pixel 100 has a photodiode as a photoelectric conversion element and pixel transistors 110. The pixel transistors 110 include a transfer transistor, a capacitance switching transistor, a reset transistor, an amplification transistor, a selection transistor, and the like. These transistors have been explained above in detail with reference to FIG. 2 and other drawings and thus will be omitted here.

As depicted in FIG. 18, in the pixel transistor 110, side walls 152 are formed laterally on the gate electrode 151 constituted typically by polysilicon, metal, or the like. Also in the pixel transistor 110, a source region and a drain region are each an impurity region in which phosphorus or arsenic is dispersed. For example, the concentration of phosphorus or arsenic is approximately 1×10¹⁸/cm³ to 5×10²¹/cm³. In FIG. 18, an impurity region 181 and an impurity region 182 are formed on the source side and the drain side, respectively, in the silicon substrate 161. The impurity region 181 on the source side and the impurity region 182 on the drain side are each a region where the concentration of n-type impurities is high.

In the pixel transistor 110, the amount of overlap of the source-side impurity region 181 with the gate electrode 151 and the side wall 152 compares with the amount of overlap of the drain-side impurity region 182 with the gate electrode 151 and the side wall 152 as follows: In this structure, the amount of overlap of the source-side impurity region 181 differs from the amount of overlap of the drain-side impurity region 182. More specifically, in the pixel transistor 110, the amount of overlap of the source-side impurity region 181 with the gate electrode 151 and the side wall 152 is smaller than the amount of overlap of the drain-side impurity region 182 with the gate electrode 151 and the side wall 152.

Here, the miniaturization of the pixel structure requires reducing the size of the side wall in the pixel transistor. Also, in terms of the structure under layout area constraints stemming from the miniaturization, the nonlinear shape (L-shape) in planar view of the channel between the source region and the drain region has been proposed in addition to the linear shape. However, reducing the side wall in size brings the source and drain impurity regions closer to the gate electrode, generating a strong electric field. The strong electric field can worsen the white spot characteristic of pixels (e.g., increasing white spots in images). With the side wall reduction thus restricted, there occurs the problem of a limited effect in improving the efficiency of layout.

In FIG. 18, the pixel transistor 110 is structured in such a manner that the amount of overlap on the source side is smaller than that on the drain side. This makes it possible to reduce the electric field on the source side even with the reduced side wall 152, thereby improving the white spot characteristic. Also, the reduced side wall 152 can improve the efficiency of layout. Incidentally, in the case where the pixel transistor 110 is a reset transistor or a capacitance switching transistor, for example, a white spot results from the strong electric field occurring between floating diffusions (FD) and is thus referred to as the FD white spot.

FIG. 19 is a diagram indicating a manufacturing method including a process for forming the structure of the present disclosure (cross-sectional structure in FIG. 18). The process depicted in FIG. 19 comes subsequent to the processes of forming the gate electrode 151 and the side wall 152 on the silicon substrate 161.

The process indicated in FIG. 19 involves injecting n-type impurities (impurity ions) obliquely at a tilt angle on the source side of the gate electrode 151 into the silicon substrate 161 (as indicated by arrows I11). The tilt angle is a predetermined angle relative to a normal line to the principal surface of the substrate. For example, the tilt angle is formed between a normal line to the surface of the silicon substrate 161 and an ion beam. The impurity injection utilizes the shadowing by the gate electrode 151 and the side wall 152 to form the impurity region 181 away from the side wall 152 on the source side. It is to be noted that, since n-type impurities are injected on the drain side without being affected by the shadowing, a structure is produced in which the amount of overlap of the source-side impurity region 181 with the gate electrode 151 and the side wall 152 is made smaller than the amount of overlap of the drain-side impurity region 182 with the gate electrode 151 and the side wall 152. This makes it possible to form the cross-sectional structure illustrated in FIG. 18.

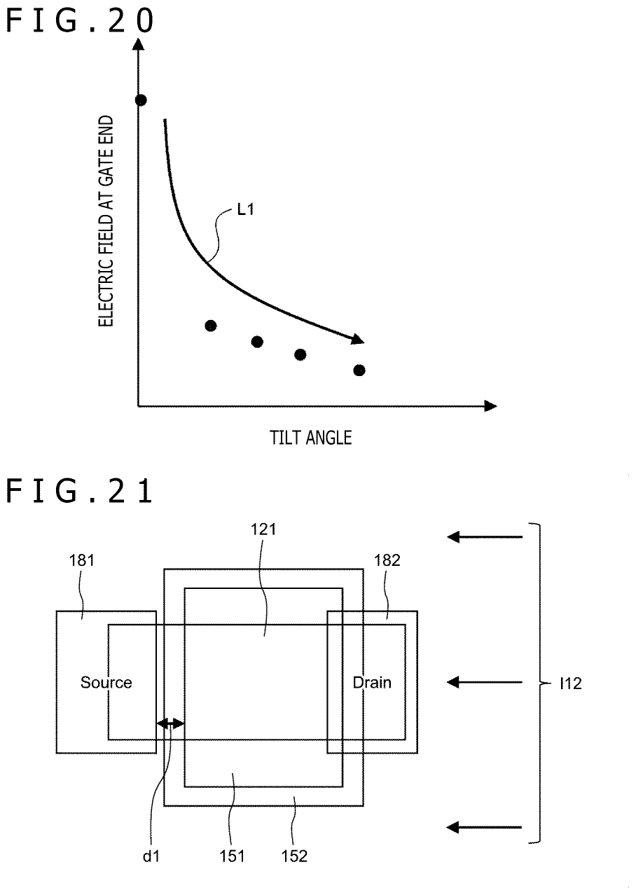

The above manufacturing method involving the injection of impurities simply at a tilt angle provides the benefit of reducing electric fields without increasing the number of processes involved. Specifically, as depicted in FIG. 20, when the magnitude of the electric field at an end of the gate electrode 151 in the pixel transistor 110 is taken on the vertical axis and the tilt angle upon injection of impurities is taken on the horizontal axis, the relation between the electric field magnitude and the impurity injection tilt angle at which the electric field is generated is plotted by a curve line L1. That is, in the case where there is no tilt angle at the time of injecting impurities, a strong electric field is generated at an end of the gate electrode 151. However, simply setting a relatively small tilt angle of 10°, 15°, or the like, for example, improves the electric field significantly. In this manner, the larger the tilt angle set for injecting impurities, the farther the impurity region 181 can be formed away from the side wall 152 on the source side. As a result, the effect of electric field reduction is enhanced, and the electric field is thereby improved.

### Second Configuration

FIG. 21 is a plan view depicting an exemplary configuration of a pixel transistor 110. FIG. 21 indicates that the pixel transistor 110 is structured in such a manner that the channel 121 has a linear-shaped region between the source region and the drain region.

In FIG. 21, in the case where the channel 121 has a linear shape, n-type impurities are injected obliquely at a tilt angle relative to the gate electrode 151 and the side wall 152 on the source side and the drain side (as indicated by arrows I12 in the drawing). At this point, the shadowing by the gate electrode 151 and the side wall 152 reduces the amount of overlap of the source-side impurity region 181 with the gate electrode 151 and the side wall 152. In contrast, the shadowing increases the amount of overlap of the drain-side impurity region 182 with the gate electrode 151 and the side wall 152.

In FIG. 21, a distance d1 between the source-side impurity region 181 and the gate electrode 151 varies depending on the tilt angle upon injection of impurities. That is, with the gate electrode 151 and the side wall 152 acting as the mask on the source side, the impurities are less likely to make way near the gate electrode 151. Whereas inroads into the drain side vary depending on the tilt angle upon injection of impurities, the white spot characteristic is determined by the electric field on the source side. This means that the white spot characteristic is not worsened by the increased amount of overlap on the drain side.

In the case where the channel 121 has a linear shape as described, impurities are injected obliquely at a tilt angle relative to the gate electrode 151 and the side wall 152 on the source side and the drain side. This allows the gate electrode 151 and the side wall 152 to act as a pseudo mask in forming the source-side impurity region 181. It is thus possible, with the source side and the drain side structured to be asymmetrical, to make the amount of overlap on the source side smaller than on the drain side.

### Third Configuration

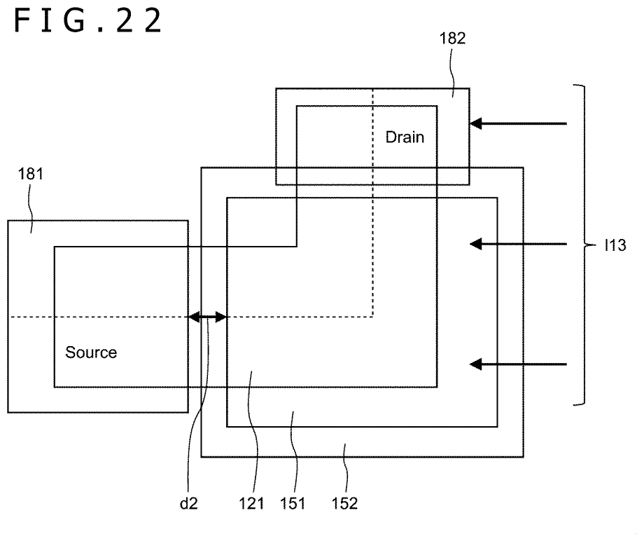

FIG. 22 is a plan view depicting an exemplary configuration of a pixel transistor 110. FIG. 22 indicates that the pixel transistor 110 is structured in such a manner that the channel 121 has a right-angle L-shaped region between the source region and the drain region.

In FIG. 22, in the case where the channel 121 has the L-shape, n-type impurities are injected obliquely at a tilt angle relative to the gate electrode 151 and the side wall 152 on the source side and the drain side (as indicated by arrows I13 in the drawing). At this point, the shadowing by the gate electrode 151 and the side wall 152 reduces the amount of overlap of the source-side impurity region 181 with the gate electrode 151 and the side wall 152. In contrast, the amount of overlap of the drain-side impurity region 182 with the gate electrode 151 and the side wall 152 remains fixed, determined solely by the width of the side wall 152.

In FIG. 22, a distance d2 between the source-side impurity region 181 and the gate electrode 151 varies depending on the tilt angle upon injection of impurities. That is, with the gate electrode 151 and the side wall 152 acting as the mask on the source side, the impurities are less likely to make way near the gate electrode 151.

In the case where the channel 121 has the L-shape as described, impurities are injected obliquely at a tilt angle relative to the gate electrode 151 and the side wall 152 on the source side and the drain side. This allows the gate electrode 151 and the side wall 152 to act as a pseudo mask in forming the source-side impurity region 181. Also, on the drain side, impurities are injected vertically regardless of the tilt angle to form the impurity region 182 corresponding to the width of the side wall 152. It is thus possible, with the source side and the drain side structured to be asymmetrical, to make the amount of overlap on the source side smaller than that on the drain side.

### Fourth Configuration

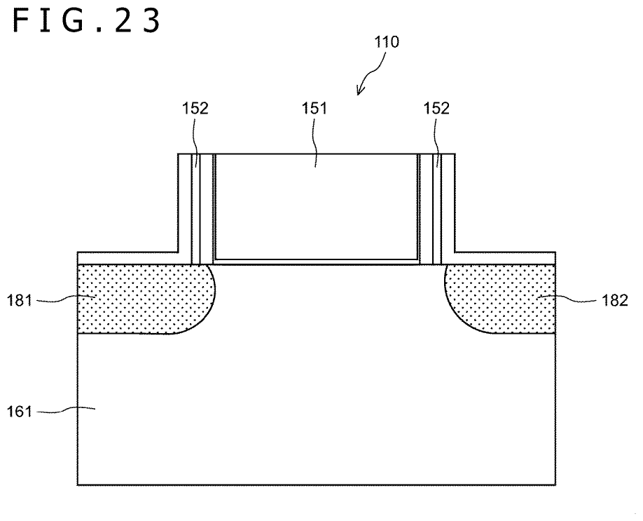

FIG. 23 is a cross-sectional diagram depicting an exemplary configuration of a pixel transistor 110.

Compared to the pixel transistor 110 in the cross-sectional diagram of FIG. 18, the amount of overlap of the source-side impurity region with the gate electrode 151 and the side wall 152 is different from the amount of overlap of the drain-side impurity region with the gate electrode 151 and the side wall 152 in the pixel transistor 110 in the cross-sectional diagram of FIG. 23. More specifically, the pixel transistor 110 in the cross-sectional diagram of FIG. 23 is structured in such a manner that the amount of overlap of the drain-side impurity region 182 with the gate electrode 151 and the side wall 152 is made smaller than the amount of overlap of the source-side impurity region 181 with the gate electrode 151 and the side wall 152.

Here, the 1/f noise is likely to be affected more by the interface state under the side wall 152 on the source side than by the interface state under the side wall 152 on the drain side. Because the pixel transistor 110 is structured to have a smaller amount of overlap on the drain side than that on the source side, the interface state under the side wall 152 on the source side is inactivated, which reduces the 1/f noise.

It is to be noted that, when the cross-sectional structure depicted in FIG. 23 is fabricated, impurities may be injected obliquely at a tilt angle relative to the gate electrode 151 on the drain side into the silicon substrate 161, for example. This allows the shadowing by the gate electrode 151 and the side wall 152 to form the impurity region 182 away from the side wall 152 on the drain side. At this point, the impurities are injected on the source side without being affected by the shadowing. This makes it possible to produce a structure in which the amount of overlap on the drain side is smaller than that on the source side (i.e., asymmetrical structure).

According to the present disclosure, as described above, the pixel transistor is structured in such a manner that the amount of overlap of the source-side impurity region with the gate electrode and the side wall is different from the amount of overlap of the drain-side impurity region with the gate electrode and the side wall. In particular, the amount of overlap of the source-side impurity region with the gate electrode and the side wall can be made smaller than the amount of overlap of the drain-side impurity region with the gate electrode and the side wall. This structure makes it possible to reduce the side wall without worsening the white spot characteristic and thereby to improve the efficiency of layout. Moreover, the source-side impurity region and the drain-side impurity region, which are asymmetrically structured, can be formed by setting a tilt angle for injection of impurities during the currently performed processes. It is thus possible to improve both the efficiency of layout and the white spot characteristic without increasing the number of processes. The pixel transistor to which the structure of the present disclosure is applied thus improves the efficiency of pixel layout and the white spot characteristic of the pixels. This in turn improves the characteristics of the pixel transistors, which results in an improvement of the pixels that include the pixel transistors structured as described. It is to be noted that, whereas the structure of the present disclosure may be applied to the pixel transistors such as the reset transistor and the capacitance switching transistor in view of improving the white spot characteristic (FD white spot), the structure of the disclosure can also be applied to other pixel transistors.

### Variations

### Oher Exemplary Configurations

In the foregoing description, it has been assumed that the solid-state imaging device 10 is a back-illuminated solid-state imaging device. Alternatively, the solid-state imaging device 10 may be a front-illuminated solid-state imaging device. The back-illuminated solid-state imaging device here is structured in such a manner that light is made incident on the upper layer (back side) opposite to the wiring layer side (front side) formed in the lower layer as viewed from the silicon substrate on which the photodiodes are provided as photoelectric conversion elements. The front-illuminated solid-state imaging device is structured such that light is made incident on the wiring layer side (front side).

The solid-state imaging device 10 is an exemplary light detecting device to which the present disclosure is applied. That is, the light detecting device to which the present disclosure is applied may be used not only as the solid-state imaging device 10 but also as any other light detecting device such as a distance measuring sensor using IR laser. Incidentally, the configuration to which the present disclosure is applied can be adopted not only by the CMOS solid-state imaging device but also by other solid-state imaging devices such as a CCD (Charge Coupled Device) solid-state imaging device.

In the solid-state imaging device 10, each of the pixels 100 arranged two-dimensionally in the pixel array section 21 may be provided with not only one photodiode, but also two or more photodiodes as the photoelectric conversion elements. Moreover, the pixel transistors provided in the pixel 100 may include not only the transfer transistor, the capacitance switching transistor, the reset transistor, the amplification transistor, and the selection transistor, but also other transistors in addition to these transistors. As another alternative, the capacitance switching transistor may not necessarily be provided as a pixel transistor. It is to be noted that, in this specification, the p-type and the n-type are examples of the first conductivity type and the second conductivity type, respectively. Alternatively, the first conductivity type and the second conductivity type may be the n-type and the p-type, respectively.

### Configuration of Electronic Equipment

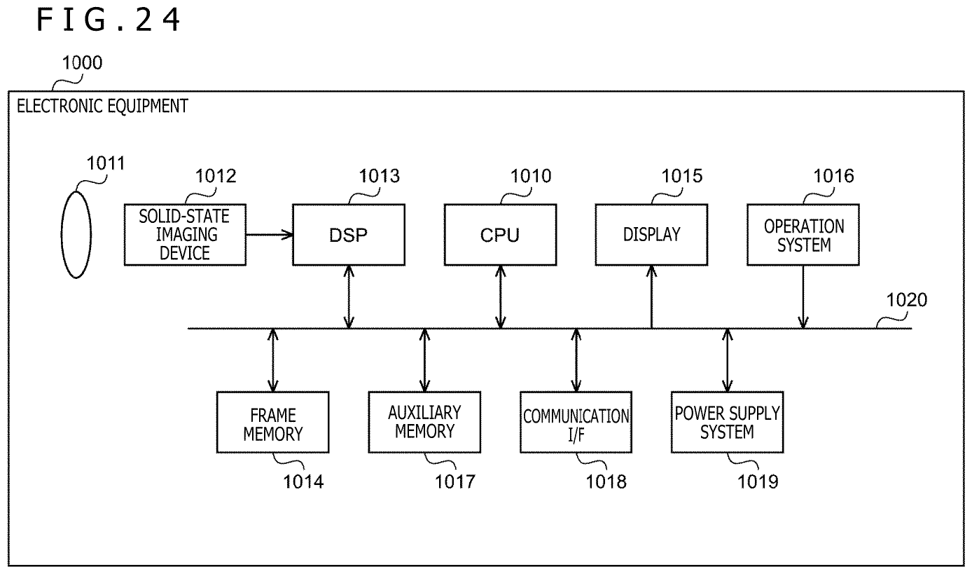

The solid-state imaging device to which the present disclosure is applied can be mounted on such electronic equipment as a smartphone, a tablet terminal, a mobile phone, a digital still camera, and a digital video camera. FIG. 24 is a block diagram depicting an exemplary configuration of electronic equipment that carries the solid-state imaging device to which the present disclosure is applied.

In FIG. 24, electronic equipment 1000 has an imaging system that includes an optical system 1011 including a lens group, a solid-state imaging device 1012 having functions corresponding to those of the solid-state imaging device 10 in FIG. 1, and a DSP (Digital Signal Processor) 1013 serving as a camera signal processing section. The electronic equipment 1000 is configured such that the imaging system is supplemented with a CPU (Central Processing Unit) 1010, a frame memory 1014, a display 1015, an operation system 1016, an auxiliary memory 1017, a communication I/F 1018, and a power supply system 1019 which are connected with one another via a bus 1020.

The CPU 1010 controls the operations of the components constituting the electronic equipment 1000. The optical system 1011 takes in incident light (image light) from a subject to form an image on a light detection surface of the solid-state imaging device 1012. The solid-state imaging device 1012 converts the quantity of the incident light focused on the light detection surface by the optical system 1011 into an electrical signal in units of pixels before outputting the electrical signal. The DSP 1013 performs predetermined signal processing on the signal output from the solid-state imaging device 1012.

The frame memory 1014 temporarily records the image data of a still or moving image captured by the imaging system. The display 1015 is a liquid crystal display or an organic EL display displaying the still or moving image taken by the imaging system. The operation system 1016 issues operation commands regarding various functions of the electronic equipment 1000 in response to the user's operations.

The auxiliary memory 1017, which is a storage medium including a semiconductor memory such as a flash memory, records the image data of the still or moving image acquired by the imaging system. The communication I/F 1018 has a communication module that supports predetermined communication systems. The communication I/F 1018 transmits the image data of the still or moving image captured by the imaging system to other types of equipment.

The power supply system 1019 supplies as needed diverse kinds of power serving as operation power to the CPU 1010, the DSP 1013, the frame memory 1014, the display 1015, the operation system 1016, the auxiliary memory 1017, and the communication I/F 1018.

### Examples of Application to Mobile Bodies

The technology of the present disclosure (the present technology) can be applied to diverse products. For example, the technology of the present disclosure can be implemented as a device to be mounted on any type of mobile bodies such as automobiles, electric vehicles, hybrid electric vehicles, motorcycles, bicycles, personal mobility devices, aircraft, drones, ships, and robots.

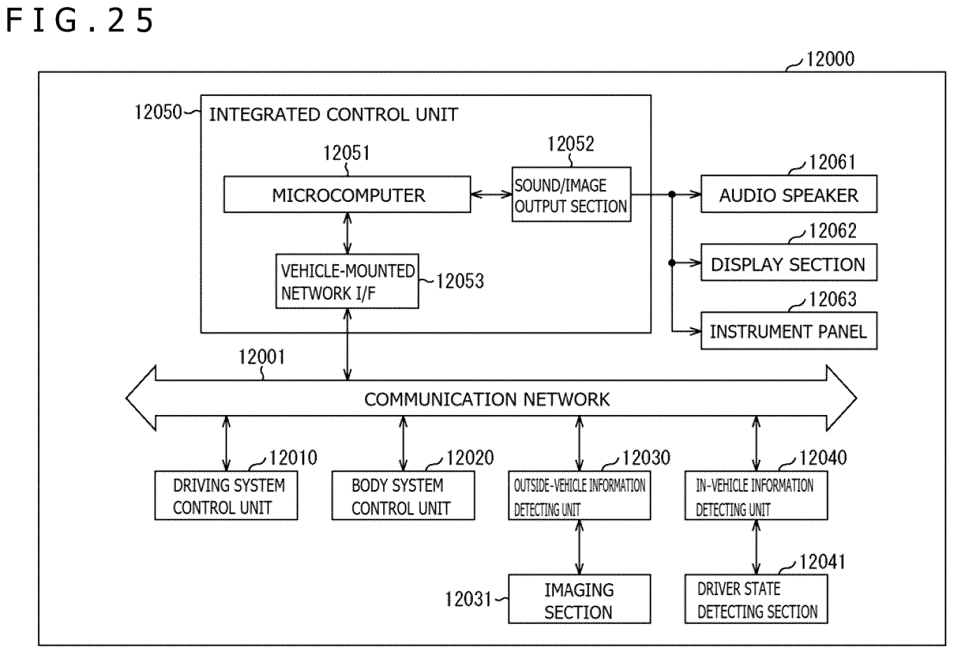

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

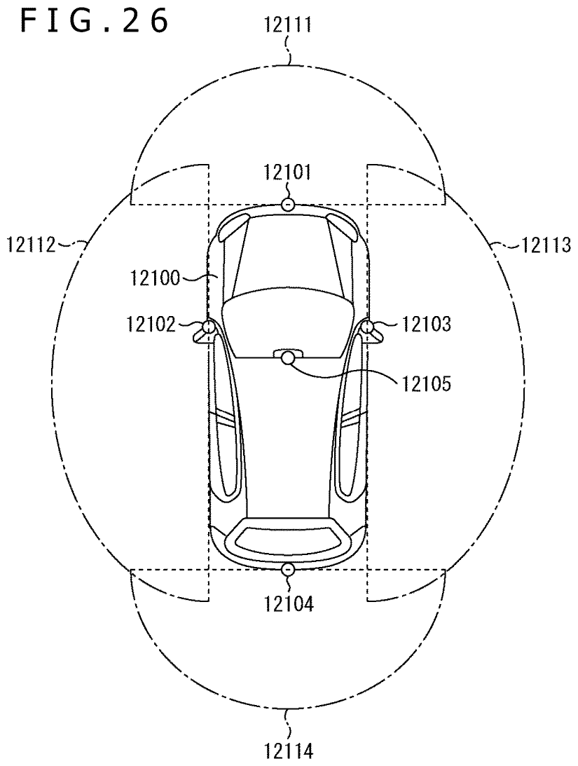

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The vehicle control system as an example to which the technology according to the present disclosure can be applied has been explained above. The technology according to the present disclosure may be applied to the imaging section 12031 from among the components discussed above. Specifically, the solid-state imaging device 10 in FIG. 1, for example, can be adopted as the imaging section 12031. Applying the technology according to the present disclosure to the imaging section 12031 allows images to be captured with higher definition. This makes it possible, for example, to recognize the target such as pedestrians more accurately.

The embodiments of the present disclosure are not limited to the embodiments discussed above and can be implemented in diverse variations as far as they are within the scope of the present disclosure. For example, the first and the second embodiments may be implemented alone or in combination. The advantageous effects stated in the present description are only examples and not limitative of the present disclosure. There may also be other advantageous effects.

The present disclosure can adopt the following configurations.
(1)

A solid-state imaging device including:
a pixel array section having a plurality of pixels arranged two-dimensionally therein, each of the pixels including a photoelectric conversion element and a pixel transistor,
in which the pixel transistor includes a transistor having a structure in which impurities are injected into a nonlinear-shaped channel in planar view with use of a self-aligned mask corresponding to a gate electrode.
(2)

The solid-state imaging device according to (1) above,
in which the pixel has an element isolation structure in which a trench penetrates in a stacking direction a silicon substrate having the photoelectric conversion element formed therein in cross-sectional view.
(3)

The solid-state imaging device according to (1) above,
in which the pixel has an element isolation structure in which impurities are injected into a silicon substrate having the photoelectric conversion element formed therein.
(4)

The solid-state imaging device according to (1) above,
in which the pixel has an element isolation structure in which a silicon substrate with the photoelectric conversion element formed therein in cross-sectional view is engraved in a stacking direction and embedded with an oxide film.
(5)

The solid-state imaging device according to (1) above,
in which the pixel has an element isolation structure in which a trench penetrates in a stacking direction a silicon substrate having the photoelectric conversion element formed therein in cross-sectional view, and an element isolation structure in which the silicon substrate is engraved in the stacking direction and embedded with an oxide film.
(6)

The solid-state imaging device according to any one of (1) to (5) above,
in which the transistor is shaped in such a manner that the channel has a right-angle region in planar view.
(7)

The solid-state imaging device according to any one of (1) to (5) above,
in which the transistor is shaped in such a manner that the channel has an obtuse-angle region in planar view.
(8)

The solid-state imaging device according to any one of (1) to (5) above,
in which the impurities are injected obliquely at a tilt angle in cross-sectional view.
(9)

The solid-state imaging device according to any one of (1) to (5) above,
in which the impurities are injected vertically in cross-sectional view.
(10)

The solid-state imaging device according to (3) above,
in which the transistor has a structure in which p-type impurities are injected into an inside of a shape of the channel with use of the self-aligned mask.
(11)

The solid-state imaging device according to (3) or (10) above,
in which the transistor has a structure in which n-type impurities are injected into an outside of a shape of the channel with use of the self-aligned mask.
(12)

The solid-state imaging device according to (1) above,
in which the photoelectric conversion element includes a photodiode, and
the pixel has an embedded photodiode structure in which the photodiode is embedded in a region away from a surface of a silicon substrate in a stacking direction in cross-sectional view and is isolated by an impurity region.
(13)

A solid-state imaging device including:
a pixel array section having a plurality of pixels arranged two-dimensionally therein, each of the pixels including a photoelectric conversion element and a pixel transistor,
in which the pixel transistor includes a transistor having a structure in which an amount of overlap of a first impurity region on a source side with a gate electrode and a side wall is different from an amount of overlap of a second impurity region on a drain side with the gate electrode and the side wall.
(14)

The solid-state imaging device according to (13) above,
in which the transistor has a structure in which the amount of overlap of the first impurity region with the gate electrode and the side wall is smaller than the amount of overlap of the second impurity region with the gate electrode and the side wall.
(15)

The solid-state imaging device according to (13) above,
in which the transistor has a structure in which the amount of overlap of the second impurity region with the gate electrode and the side wall is smaller than the amount of overlap of the first impurity region with the gate electrode and the side wall.
(16)

The solid-state imaging device according to any one of (13) to (15) above,
in which the transistor has a structure in which, following formation of the gate electrode and the side wall, by injecting impurities on the source side or the drain side of the gate electrode at a tilt angle, and by using the gate electrode and the side wall to provide shadowing, impurities are injected away from the source-side or the drain-side side wall so as to form the first impurity region and the second impurity region.
(17)

The solid-state imaging device according to any one of (13) to (15) above,
in which a region of the source and a region of the drain each include an impurity region having phosphorus or arsenic dispersed therein.
(18)

The solid-state imaging device according to (13) above,
in which the transistor is shaped in such a manner that a channel formed between a region of the source and a region of the drain has a right-angle region in planar view.
(19)

The solid-state imaging device according to (18) above,
in which the transistor has a structure in which the amount of overlap of the first impurity region with the gate electrode and the side wall is smaller than the amount of overlap of the second impurity region with the gate electrode and the side wall.
(20)

The solid-state imaging device according to (18) above,
in which the transistor has a structure in which the amount of overlap of the second impurity region with the gate electrode and the side wall is smaller than the amount of overlap of the first impurity region with the gate electrode and the side wall.
(21)

The solid-state imaging device according to any one of (18) to (20) above,
in which the transistor has a structure in which, following formation of the gate electrode and the side wall, by injecting impurities on the source side or the drain side of the gate electrode at a tilt angle, and by using the gate electrode and the side wall to provide shadowing, impurities are injected away from the source-side or the drain-side side wall so as to form the first impurity region and the second impurity region.
(22)

The solid-state imaging device according to any one of (18) to (20) above,
in which the region of the source and the region of the drain are each an impurity region having phosphorus or arsenic dispersed therein.

### REFERENCE SIGNS LIST

10: Solid-state imaging device
21: Pixel array section
22: Vertical drive section
23: Column signal processing section
24: Horizontal drive section
25: Output section
26: Control section
42: Vertical signal line
100: Pixel
110: Pixel transistor
111: Transfer transistor
112: Capacitance switching transistor
113: Reset transistor
114: Amplification transistor
115: Selection transistor
121, 121-1, 121-2: FD
121: Channel
131: Element isolation section
132: Element isolation section
151: Gate electrode
152: Side wall
161: Silicon substrate
162: Impurity region
171: Photodiode
172: Impurity region
181: Impurity region
182: Impurity region
1000: Electronic equipment
1012: Solid-state imaging device

What is claimed is:

1. A solid-state imaging device comprising:
a pixel array section having a plurality of pixels arranged two-dimensionally therein, each of the pixels including a photoelectric conversion element and a pixel transistor,
wherein the pixel transistor includes a transistor having a structure in which impurities are injected into a nonlinear-shaped channel in planar view with use of a self-aligned mask corresponding to a gate electrode.

2. The solid-state imaging device according to claim 1,
wherein the pixel has an element isolation structure in which a trench penetrates in a stacking direction a silicon substrate having the photoelectric conversion element formed therein in cross-sectional view.

3. The solid-state imaging device according to claim 1,
wherein the pixel has an element isolation structure in which impurities are injected into a silicon substrate having the photoelectric conversion element formed therein.

4. The solid-state imaging device according to claim 1,
wherein the pixel has an element isolation structure in which a silicon substrate with the photoelectric conversion element formed therein in cross-sectional view is engraved in a stacking direction and embedded with an oxide film.

5. The solid-state imaging device according to claim 1,
wherein the pixel has an element isolation structure in which a trench penetrates in a stacking direction a silicon substrate having the photoelectric conversion element formed therein in cross-sectional view, and an element isolation structure in which the silicon substrate is engraved in the stacking direction and embedded with an oxide film.

6. The solid-state imaging device according to claim 1,
wherein the transistor is shaped in such a manner that the channel has a right-angle region in planar view.

7. The solid-state imaging device according to claim 1,
wherein the transistor is shaped in such a manner that the channel has an obtuse-angle region in planar view.

8. The solid-state imaging device according to claim 1,
wherein the impurities are injected obliquely at a tilt angle in cross-sectional view.

9. The solid-state imaging device according to claim 1,
wherein the impurities are injected vertically in cross-sectional view.

10. The solid-state imaging device according to claim 3,
wherein the transistor has a structure in which p-type impurities are injected into an inside of a shape of the channel with use of the self-aligned mask.

11. The solid-state imaging device according to claim 3,
wherein the transistor has a structure in which n-type impurities are injected into an outside of a shape of the channel with use of the self-aligned mask.

12. The solid-state imaging device according to claim 1,
wherein the photoelectric conversion element includes a photodiode, and
the pixel has an embedded photodiode structure in which the photodiode is embedded in a region away from a surface of a silicon substrate in a stacking direction in cross-sectional view and is isolated by an impurity region.

13. A solid-state imaging device comprising:
a pixel array section having a plurality of pixels arranged two-dimensionally therein, each of the pixels including a photoelectric conversion element and a pixel transistor,
wherein the pixel transistor includes a transistor having a structure in which an amount of overlap of a first impurity region on a source side with a gate electrode and a side wall is different from an amount of overlap of a second impurity region on a drain side with the gate electrode and the side wall.

14. The solid-state imaging device according to claim 13,
wherein the transistor has a structure in which the amount of overlap of the first impurity region with the gate electrode and the side wall is smaller than the amount of overlap of the second impurity region with the gate electrode and the side wall.

15. The solid-state imaging device according to claim 13,
wherein the transistor has a structure in which the amount of overlap of the second impurity region with the gate electrode and the side wall is smaller than the amount of overlap of the first impurity region with the gate electrode and the side wall.

16. The solid-state imaging device according to claim 13,
wherein the transistor has a structure in which, following formation of the gate electrode and the side wall, by injecting impurities on the source side or the drain side of the gate electrode at a tilt angle, and by using the gate electrode and the side wall to provide shadowing, impurities are injected away from the source-side or the drain-side side wall so as to form the first impurity region and the second impurity region.

17. The solid-state imaging device according to claim 13,
wherein a region of the source and a region of the drain each include an impurity region having phosphorus or arsenic dispersed therein.

18. The solid-state imaging device according to claim 13,
wherein the transistor is shaped in such a manner that a channel formed between a region of the source and a region of the drain has a right-angle region in planar view.

19. The solid-state imaging device according to claim 18,
wherein the transistor has a structure in which the amount of overlap of the first impurity region with the gate electrode and the side wall is smaller than the amount of overlap of the second impurity region with the gate electrode and the side wall.

20. The solid-state imaging device according to claim 18,
wherein the transistor has a structure in which the amount of overlap of the second impurity region with the gate electrode and the side wall is smaller than the amount of overlap of the first impurity region with the gate electrode and the side wall.

21. The solid-state imaging device according to claim 18,
wherein the transistor has a structure in which, following formation of the gate electrode and the side wall, by injecting impurities on the source side or the drain side of the gate electrode at a tilt angle, and by using the gate electrode and the side wall to provide shadowing, impurities are injected away from the source-side or the drain-side side wall so as to form the first impurity region and the second impurity region.

22. The solid-state imaging device according to claim 18,
wherein the region of the source and the region of the drain are each an impurity region having phosphorus or arsenic dispersed therein.
